(19) United States
(12) Patent Application Publication
(10) Pub. No.: US 2024/0388290 A1
(43) Pub. Date: Nov. 21, 2024

(54) KEYSWITCH ASSEMBLY

(71) Applicant: Darfon Electronics Corp., Taoyuan City (TW)

(72) Inventors: Chen YANG, Taoyuan City (TW); Shao-Lun HSIAO, Taoyuan City (TW); Yu-Chun HSIEH, Taoyuan City (TW)

(21) Appl. No.: 18/663,389

(22) Filed: May 14, 2024

Related U.S. Application Data
(60) Provisional application No. 63/503,014, filed on May 18, 2023.

(30) Foreign Application Priority Data
Sep. 5, 2023 (TW) 112133640
Dec. 6, 2023 (TW) 112147539

(51) Int. Cl. H03K 17/94; H01H 13/04

(52) U.S. Cl. CPC H03K 17/941; H01H 13/04

(57) ABSTRACT

A keyswitch assembly includes a keycap, a lifting mechanism, a shield, and a substrate. The lifting mechanism includes a keycap end coupled to the keycap and is capable of being driven by a force to move downward by a distance. The shield extends from the keycap end or the keycap and is movable along with the keycap end or the keycap. The substrate is disposed below the lifting mechanism and includes a sensing switch and a keyswitch circuit electrically connected to each other. The sensing switch has a signal channel and is configured to sense a change in sensed intensity caused by interference of the shield with the signal channel to cause the keyswitch circuit to generate at least one keyswitch signal. During movement of the shield with the keycap end or the keycap, the shield interferes with the signal channel as much as possible throughout the entire distance.

### CROSS REFERENCE TO RELATED APPLICATIONS

This application claims the priority benefit of U.S. provisional application Ser. No. 63/503,014, filed on May 18, 2023 and also claimed the priority benefit of Taiwan patent application No. 112133640, filed on Sep. 5, 2023, and Taiwan patent application No. 112147539, filed on Dec. 6, 2023. The entirety of the above-mentioned patent applications is hereby incorporated by reference herein and made a part of this specification.

### BACKGROUND OF THE INVENTION

### 1. Field of the Invention

The invention generally relates to a keyboard. Particularly, the invention relates to a keyswitch assembly.

### 2. Description of the Prior Art

Mechanical keys, membrane switch keys, and optical sensing switch keys are the key types commonly used in conventional keyboards. Mechanical keys are switches that generate signals based on whether the metal piece and the metal contact are conducted. However, conventional mechanical keys have a complicated structure and are large in size, not suitable for use in electronic devices in need of thinness (such as laptop computers).

Therefore, with the increasing demand for thinner keyboards, in addition to using membrane switch keys in the keyboard design, more and more keyboards are beginning to use optical sensing switch keys as the key type of the keyboard. Generally, optical sensing switch keys use the light emitter and the light receiver as the switch to generate signals. That is, pressing the keycap drives the shield to move between the light emitter and the light receiver to interfere with the light emitted from the light emitter to the light receiver, causing the light receiver to generate a signal difference due to the change in amount of light received. The actuation signal is generated based on whether the signal difference reaches a predetermined threshold.

### SUMMARY OF THE INVENTION

It is an object of the invention to provide a multi-stage optical sensing keyswitch, which allows non-professional users to operate smoothly, i.e., during a travel distance of a same pressing operation, the user does not need to undergo extreme training in finger pressing techniques, and can use his/her fingers to control the pressing depth to output different keyswitch signals.

In an embodiment, the invention provides a keyswitch assembly including a keycap, a lifting mechanism, a shield, and a substrate. The lifting mechanism has a keycap end coupled to the keycap and is capable of being driven by a force to move downward by a distance. The shield extends from the keycap end or the keycap and is movable along with the keycap end or the keycap. The substrate is disposed below the lifting mechanism. The substrate includes a sensing switch and a keyswitch circuit electrically connected to each other. The sensing switch has a signal channel and is configured to sense a change in sensed intensity caused by interference of the shield with the signal channel to cause the keyswitch circuit to generate at least one keyswitch signal. When the shield shields two opposite ends of the signal channel at the same time, the signal channel is not completely shielded by the shield.

In another embodiment, the invention provides a keyswitch assembly including a keycap, a lifting mechanism, a linking member, and a substrate. The lifting mechanism has a keycap end coupled to the keycap and is capable of being driven by a force to move downward by a distance. The linking member is movably against the lifting mechanism or the keycap and capable of moving along with the keycap end or the keycap. The linking member has a shield. The substrate is disposed below the lifting mechanism. The substrate includes a sensing switch and a keyswitch circuit electrically connected to each other. The sensing switch has a signal channel and is configured to sense a change in sensed intensity caused by interference of the shield with the signal channel to cause the keyswitch circuit to generate at least one keyswitch signal. In a single travel distance of the lifting mechanism, a shield flipping angle of the shield is larger than a frame flipping angle of the keycap end.

In yet another embodiment of the invention, the invention provides a keyswitch assembly including a keycap, a lifting mechanism, a linking member, and a substrate. The lifting mechanism has a keycap end coupled to the keycap. The keycap end is capable of being driven by a force to move downward by a distance from an upper point to a lower point. The linking member is movably against the lifting mechanism or the keycap and capable of moving along with the keycap end or the keycap. The linking member has a shield. The substrate is disposed below the lifting mechanism. The substrate includes a sensing switch and a keyswitch circuit electrically connected to each other. The sensing switch has a signal channel and is configured to sense a change in sensed intensity caused by interference of the shield with the signal channel to cause the keyswitch circuit to generate at least one keyswitch signal. The lifting mechanism has a pivot point, the linking member has a linkage fulcrum, and when the keycap end is at the lower point, the linkage fulcrum is located between the keycap end and the pivot point.

Through the above design, the keyswitch assembly of the invention can not only have a thin structure design, but also achieve the purpose of increasing the effective light-shielding distance, so almost the entire keyswitch travel distance can have the effect of interfering the sensed intensity.

### BRIEF DESCRIPTION OF THE DRAWINGS

FIG. 1 is a schematic view of a curve showing the relationship between the travel distance and the output voltage in a first embodiment of the invention.

FIG. 2 is a schematic view of the keyswitch assembly in a second embodiment of the invention.

FIG. 3 is a schematic exploded view of the keyswitch assembly in the second embodiment of the invention.

FIG. 4 is a schematic exploded view of the second embodiment after separating the keycap.

FIG. 5 is a schematic top view of the second embodiment of the invention after removing the keycap.

FIG. 6 is a schematic cross-sectional view of FIG. 5 along the A-A direction in the non-pressed state.

FIG. 7 is a partially enlarged schematic view of the shield in FIG. 6.

FIG. 8 is a schematic cross-sectional view of FIG. 5 along the B-B direction in the non-pressed state.

FIG. 9 is a schematic cross-sectional view of FIG. 5 along the A-A direction in the pressed state.

FIG. 10 is a schematic cross-sectional view of FIG. 5 along the B-B direction in the pressed state.

FIG. 11 is a schematic view showing the angle of the shield of the second embodiment in the non-pressed state.

FIG. 12 is a schematic view of a curve showing the relationship between travel distance and output voltage in the second embodiment of the invention.

FIG. 13 is a schematic view showing the shield of the second embodiment at different positions.

FIG. 14 is a schematic view of an implementation of the structure of the shield of the invention.

FIG. 15 is a schematic view of another implementation of the structure of the shield of the invention.

FIG. 16 is a schematic exploded view of the keyswitch assembly in a third embodiment of the invention.

FIG. 17 is a schematic exploded view of the third embodiment after separating the keycap.

FIG. 18 is a schematic top view of the third embodiment of the invention after removing the keycap.

FIG. 19 is a schematic cross-sectional view of FIG. 18 along the C-C direction in the non-pressed state.

FIG. 20 is a schematic cross-sectional view of FIG. 18 along the D-D direction in the non-pressed state.

FIG. 21 is a schematic view showing the angle of the shield of the third embodiment in the non-pressed state.

FIG. 22 is a schematic cross-sectional view of FIG. 18 along the C-C direction in the pressed state.

FIG. 23 is a schematic cross-sectional view of FIG. 18 along the D-D direction in the pressed state.

FIG. 24 is a schematic view showing the actions of the shield of the third embodiment.

FIG. 25 is a schematic view showing the linkage slope and the frame slope in the third embodiment.

FIG. 26 is a schematic view showing the linkage slope and the equivalent slope in the third embodiment.

FIG. 27 is a schematic view showing the relative positions of the linkage fulcrum, the pivot point, and the keycap end in the third embodiment.

### DETAILED DESCRIPTION OF THE PREFERRED EMBODIMENT

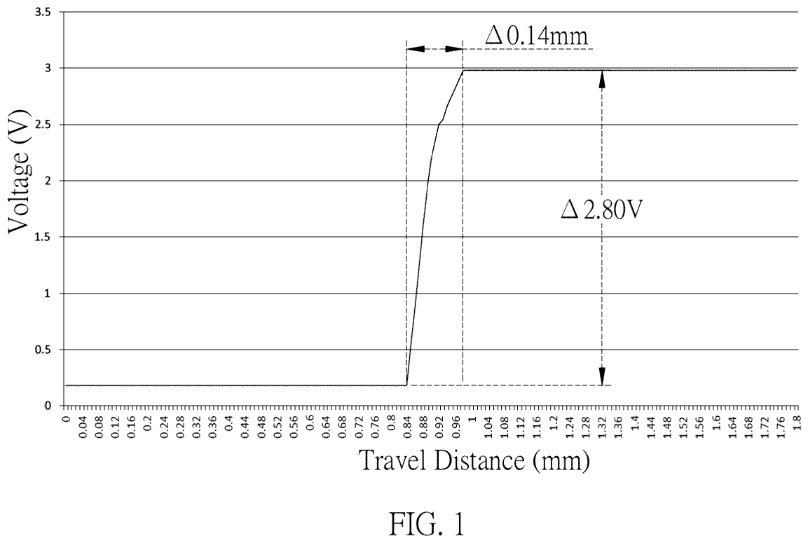

Referring to FIG. 1, in a first embodiment, a schematic view of a curve showing the relationship between the travel distance and the output voltage of an optical keyswitch assembly is illustrated. As shown in FIG. 1, only the 0.84 mm to 0.98 mm of the total travel distance (about 1.8 mm) of the keyswitch being pressed is considered as the effective light-shielding distance, within which the shield can interfere with the light emitted from the light emitter to the light sensor. This embodiment attempts to adopt the keyswitch assembly with the characteristics of FIG. 1 to design a multi-stage control. By configuring the firmware of the keyboard controller, different keyswitch signals can be generated based on the interference of the shield with the light-sensing window (corresponding to the output voltage from the light sensor) caused by the magnitude of force pressing on the keyswitch. For example, the effective distance of the shield can be divided into 2 stages, 0.07 mm for each stage. In other words, when the shield reaches the sensing window, if the keyswitch is further pressed 0.07 mm by the user, the shield will simultaneously move to interfere with the sensing window by 0.07 mm, and a light-pressing signal will be outputted as the output signal. When the keyswitch is continuously pressed to reach 0.14 mm, the shield completely shields the sensing window of 0.14 mm, and a heavy-pressing signal will be outputted as the output signal. The control parameters of this embodiment is within the interval of the effective travel distance of the shield, and the keyswitch travel distance is consistent with the travel distance of the shield.

However, as shown in FIG. 1, for a total travel distance of 1.8 mm, when the keyswitch moves downward to 0.84 mm, the shield reaches the upper end of the sensing window; when the keyswitch moves downward to 0.91 mm, the light-pressing signal will be actuated; when the keyswitch moves further downward to 0.98 mm, the heavy-pressing signal will be actuated; when the keyswitch continuously moves downward from 0.98 mm to 1.8 mm, the keyswitch reaches the lowest point. In a practical experimental test, it is found that though the light-pressing signal is actually actuated at 0.91 mm, it seems not difficult for ordinary users to operate with their fingers. However, the problem is that the distance between actuation points of the light-pressing signal and the heavy-pressing signal is only 0.07 mm, resulting in a high success rate of heavily pressing the keyswitch by users and also resulting in a high faulty rate caused by heavily pressing the keyswitch which is intended to be lightly pressed.

Moreover, the keyswitch based on the optical sensing characteristic of FIG. 1 can be configured to have another settings. For example, the actuation point of light-pressing signal is maintained at 0.86 mm of the total travel distance, and the actuation point of the heavy-pressing signal is maintained at 0.98 mm of the total travel distance. In other words, the actuation interval between the light-pressing signal and the heavy-pressing signal is increased to 0.12 mm. However, after practical experimental tests, even if the actuation interval between the light-pressing signal and the heavy-pressing signal is increased, the false actuation rate is still too high, which means that the control difference of 0.12 mm is still too harsh for users. Although the pressing accuracy can be improved through repeated rigorous trainings, this is not the purpose of the invention.

Based on the enlightenment from the foregoing embodiment, it is necessary to increase the effective light-shielding distance. However, when developing technical solutions to improve the effective light-shielding distance, it is found that some are not feasible. For example, in order to meet the thinning requirement, it is not possible to increase the travel distance of each stage of the multi-stage control by increasing the total travel distance or the height of the highest point of the keyswitch. Therefore, subsequent embodiments of the invention attempt to increase the effective light-shielding distance without increasing the total travel distance of the keyswitch to greatly reduce the invalid travel distance that does not change the light-shielding ratio. Embodiments of the invention further attempt to make the moving distance of the shield that actually affects the shielding area be larger than the moving distance of the keyswitches, requiring significant changes of the shielding structure and operating mechanism. Moreover, in order to take into account the pressing strength, the tactile feedback, and even the backlight effect, it is also necessary to design a suitable support frame and select a proper elastic member.

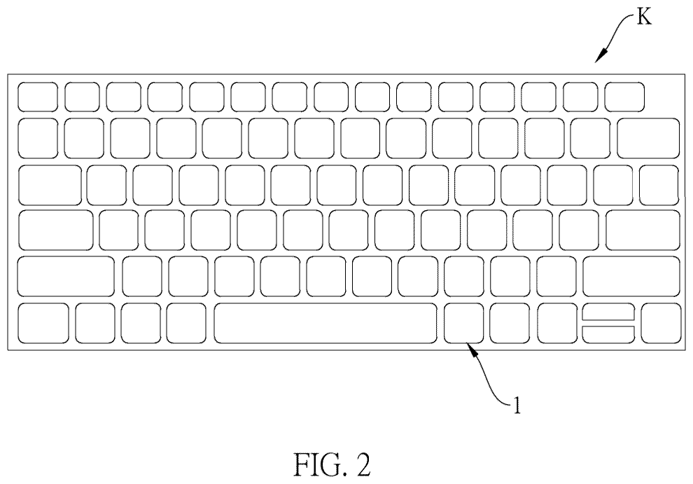

In order to illustrate the invention more clearly, the following embodiments are provided and described in detail with reference to the drawings. Referring to FIG. 2 to FIG. 5, the keyswitch assembly 1 of a second embodiment of the invention is illustrated. In this embodiment, the keyswitch assembly 1 is explained by taking one of the keys in the keyboard K of FIG. 2 as an example. In practical applications, the keyswitch assembly 1 can be the keys in a keyboard of an electronic device (e.g. laptop computer) or the keys in a keyboard of an interface for operating mechanical equipment, not limited to the keyboard K. The number of keys can be plural, and the keys can be arranged on the substrate 11. The key can be a standard key (square key), a multiple key (space, shift, enter, caps lock, backspace) or a small key (function key or direction key). The substrate 11 can be a rigid plate made of metal or plastic materials.

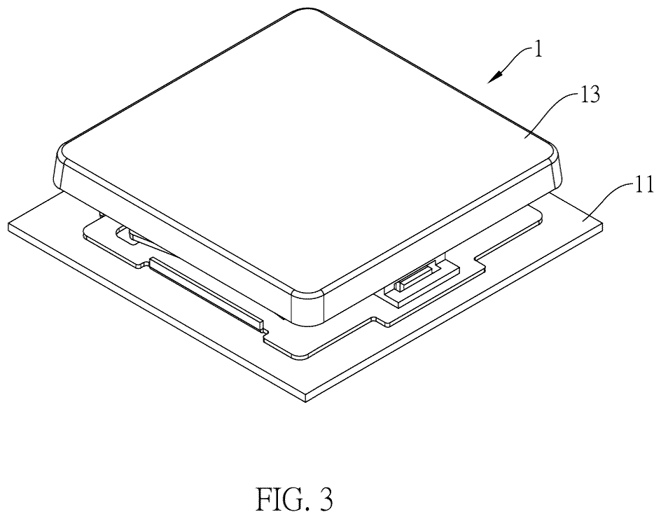

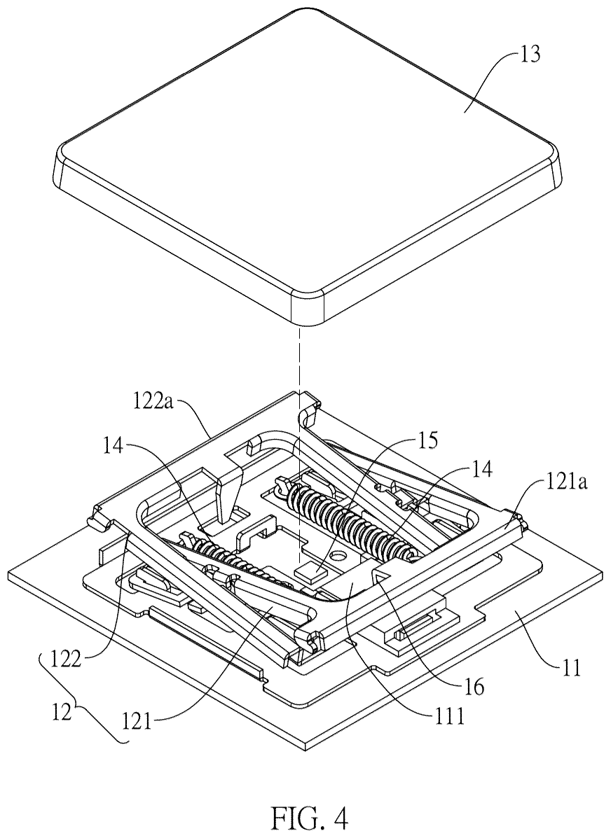

Referring to FIGS. 3 and 4, in the second embodiment, the keyswitch assembly 1 includes a substrate 11, a lifting mechanism 12, a keycap 13, a restoring member, a backlight source 15, and a shield 16.

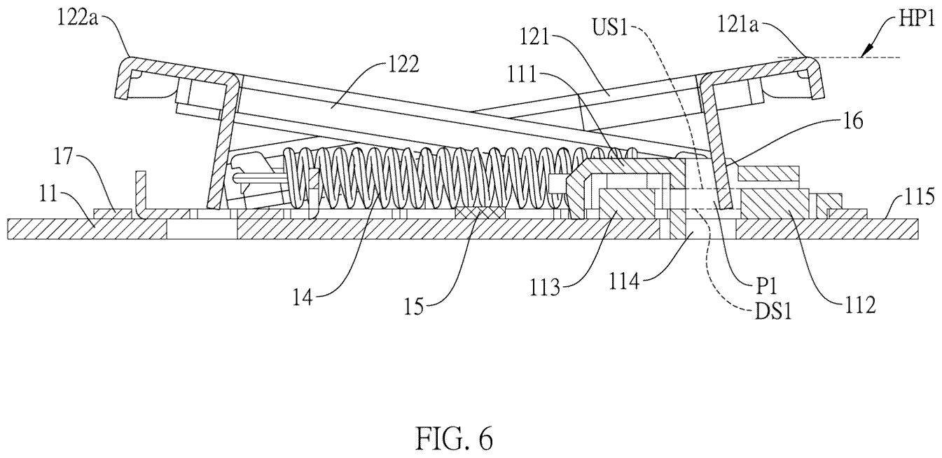

Referring to FIGS. 6 to 8, the substrate 11 includes a sensing switch, an optical member 111, and a keyswitch circuit 115. More specifically, in this embodiment, the sensing switch includes a sensing light source 112 and a light sensor 113 disposed opposite to each other. The sensing light source 112 can be an infrared light-emitting diode (LED), and the light sensor 113 is an infrared sensor. In practical applications, other light sources and sensors of different wavelengths (such as red light, white light, blue light) can be implemented. The substrate 11 has a through hole 114 between the sensing light source 112 and the light sensor 113.

The optical member 111 covers the light sensor 113 of the sensing switch, thereby reducing interference of other lights with the reception of the light sensor 113 through the shielding of the optical member 111. The optical member 111 has an opening 111a, and the light sensor 113 faces the sensing light source 112 through the opening 111a, so a signal channel P1 is formed between the light sensor 113 and the sensing light source 112 through the opening 111a. According to the height and the width of the signal channel P1, the signal channel P1 is configured with two thresholds at two opposite ends between the sensing light source 112 and the light sensor 113. The two thresholds at two opposite ends of the signal channel P1 may be aligned in a vertical direction or a horizontal direction, either of which is preferably perpendicular to the signal channel P1 between the sensing light source 112 and the light sensor 113.

For example, the signal channel P1 can be defined with an upper threshold US1 and a lower threshold DS1 at two ends in the vertical (or height, stacking) direction, so the upper threshold US1 and the lower threshold DS1 define the upper boundary and the lower boundary of the signal channel P1, respectively. The lower threshold DS1 is closer to the upper surface of the substrate 11 than the upper threshold US1. In an embodiment, the upper threshold US1 is defined by the upper edge of the opening 111a, and the lower threshold DS1 is defined by the lower edge of the opening 111a. For example, the location and the width of the upper threshold US1 correspond to the location and the width of the upper edge of the opening 111a, and the location and the width of the lower threshold DS1 correspond to the location and the width of the lower edge of the opening 111a, but not limited thereto. In another embodiment that the opening 111a is not provided, or the opening 111a has a larger dimension, the two thresholds are preferably defined at positions where the space for allowing the light to pass from the sensing light source 112 to the light sensor 113 through the signal channel P1 can be defined. When the signal channel P1 is interfered, the sensed intensity of the light sensor 113 will be changed. In this embodiment, the light sensor 113 can output a voltage of 0-3 volts according to the sensed intensity of optical signal, and the output voltage will be increased as the sensed intensity is reduced. In practical applications, the light sensor can be replaced with a type of light sensor that outputs a lower voltage as the sensed intensity is reduced.

The keyswitch circuit 115 can be a printed circuit on the surface of the substrate 11 and is configured to electrically connect the light sensor 113. When the output voltage of the light sensor 113 of the sensing switch is changed, the keyswitch circuit 115 will generate the keyswitch signal. More specifically, in this embodiment, the keyswitch circuit 115 is configured with a plurality of threshold values, which are different from each other. When the sensed intensity of the light sensor 113 reaches a corresponding threshold value, the keyswitch circuit 115 will generate a keyswitch signal corresponding to the reached threshold value. In other words, the keyswitch circuit 115 can be configured with multi-stage signal outputs. For example, when the light sensor 113 outputs a voltage less than 0.3V (i.e., 0.3V<output voltage) in response to the sensed optical signal, the keyswitch circuit 115 outputs a null signal. When the voltage output by the light sensor 113 reaches 0.3V (e.g. 0.3V<=output voltage<1.8V), the keyswitch circuit 115 outputs a first keyswitch signal. When the light sensor 113 outputs a voltage of 1.8V (i.e., output voltage=>1.8V), the keyswitch circuit 115 outputs a second keyswitch signal.

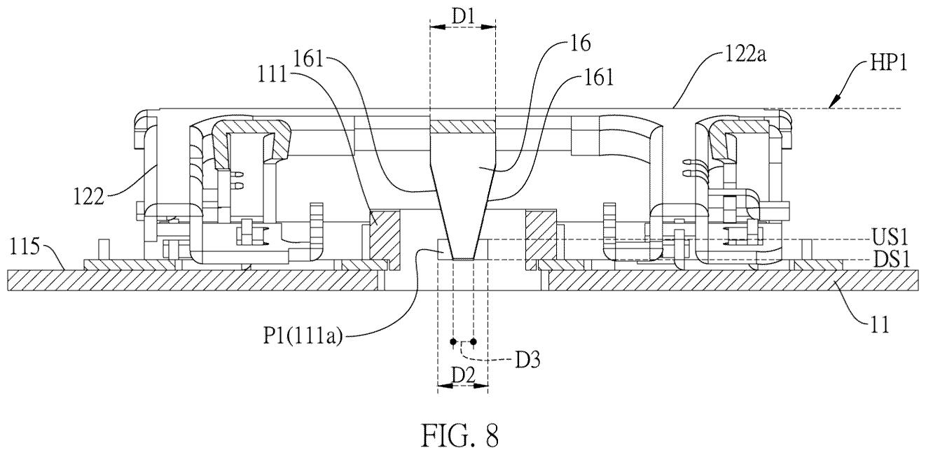

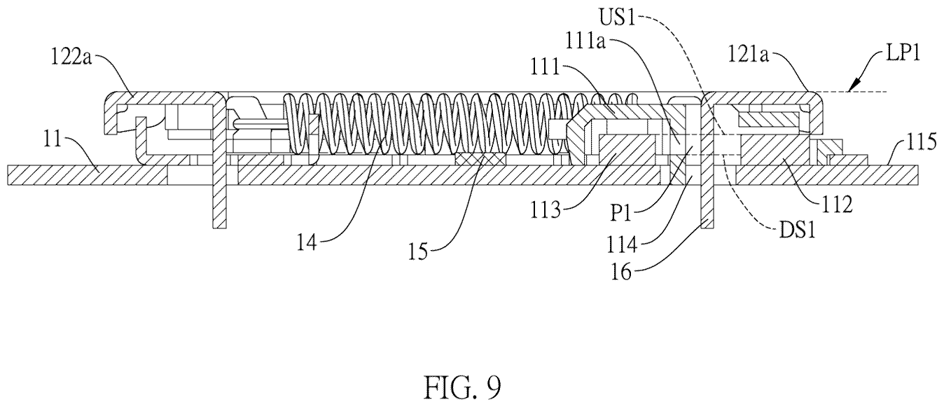

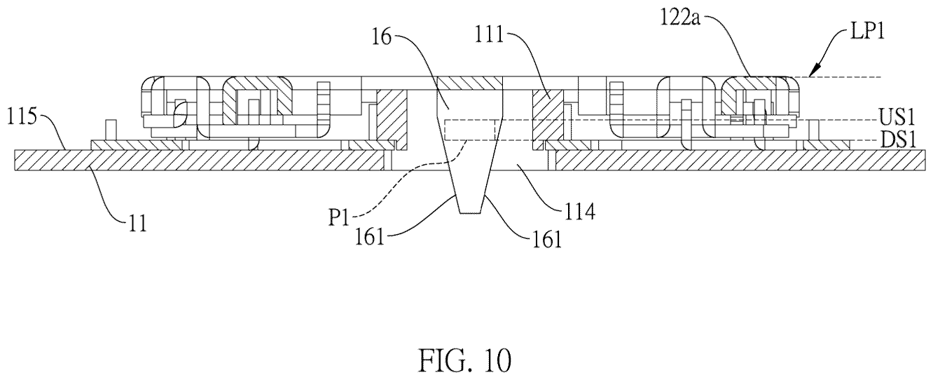

The lifting mechanism 12 includes a first frame 121 and a second frame 122. The first frame 121 and the second frame 122 are connected to each other and rotatable relative to each other. The top portion of each of the first frame 121 and the second frame 122 constitutes a keycap end 121a (122a) and is movably connected to the keycap 13. Moreover, the bottom portion of each of the first frame 121 and the second frame 122 constitutes a substrate end and is movably connected to the substrate. When the user exerts a force on the keycap 13, the lifting mechanism 12 is driven by the force to move downward by a distance to drive the keycap end 121a (122a) to move from an upper point HP1 (as shown in FIG. 6 and FIG. 8) to a lower point LP1 (as shown in FIG. 9 and FIG. 10).

The restoring member can be two tension springs 14, which are located between the first frame 121 and the second frame 122 and connected to the hooks at the substrate ends of the first frame 121 and the second frame 122. When the user exerts the force on the keycap 13 to drive the lifting mechanism 12 to move downward, the two tension springs 14 are stretched. When the user reduces or removes the force from the keycap 13, the two tension springs 14 are contracted to pull the first frame 121 and the second frame 122, enabling the keycap end 121a (122a) to return from the lower point LP1 to the upper point HP1. In addition to the tension spring, the restoring member can be implemented as a pushing spring, an elastic member, etc. and disposed between the substrate 11 and the lifting mechanism 12 or between the keycap 13 and the lifting mechanism 12 according to the force direction to achieve the same purpose.

The backlight source 15 can be a light-emitting diode (LED), which is disposed on the substrate 11 at the central region defined by the lifting mechanism 12 and configured to emit light, which is projected to the keycap 13, so the pattern (not shown) on the top of the keycap 13 can be penetrated by the light to display the pattern content. In addition, the opening 111a of the optical member 111 faces away from the central region where the backlight source 15 is located to prevent the light generated by the backlight source 15 from interfering with the sensed intensity of the light sensor 113.

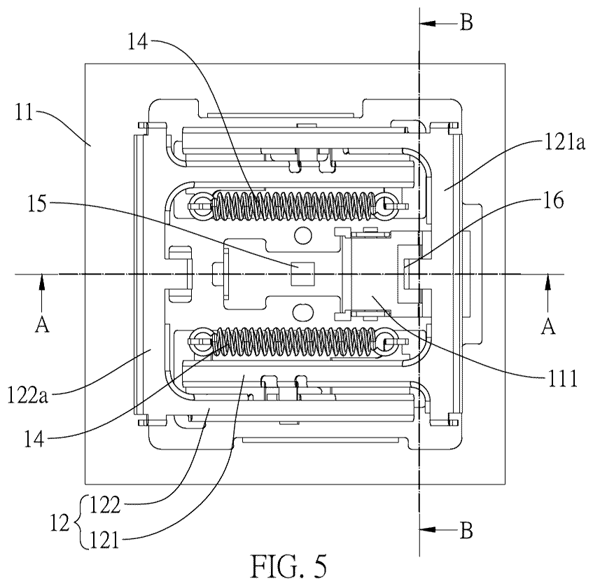

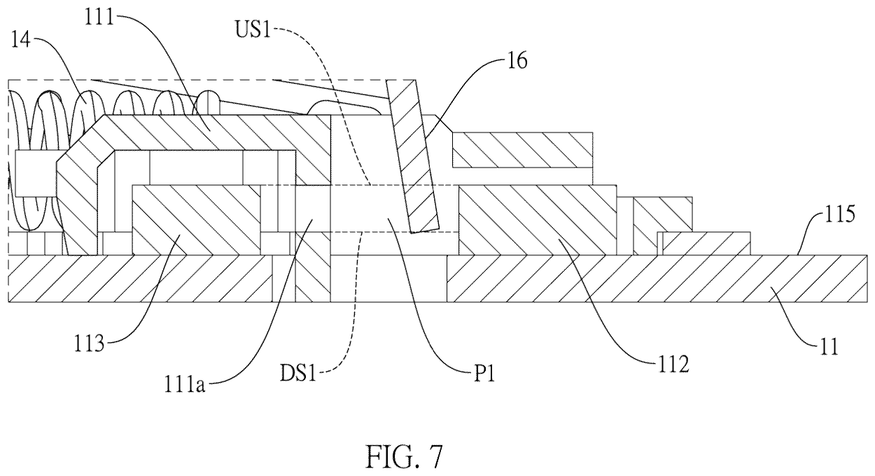

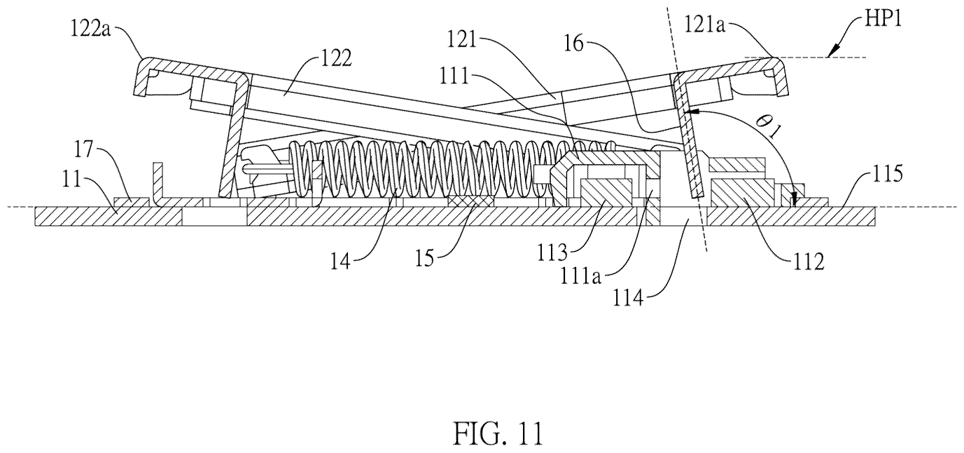

Referring to FIG. 6, the shield 16 extends from the keycap end 121a toward the signal channel P1 to be located between the keycap end 121a and the backlight source 15. It can be seen from FIG. 8 that in the cross-sectional view along the B-B direction in FIG. 5, which is a direction perpendicular to the optical axis of the sensing light source 112 (i.e., perpendicular to the extension direction of the signal channel P1 from the sensing light source 112 to the light sensor 113), the shield 16 has a pair of inclined edges 161 at two opposite sides, so the width of the shield 16 is gradually decreased from the portion connected to the keycap end 121a to the free end thereof. The width D1 of the shield 16 at the portion connected to the keycap end 121a is larger than the width D2 of the opening 111a, and the width D3 of the shield 16 at the free end thereof is smaller than the width D2 of the opening 111a. In an embodiment, the width D2 of the opening 111a defines the width of the signal channel P1. For example, the width of the signal channel P1 can be the width D2. The free end of the shield 16 passes (or extends) through the upper threshold US1 of the signal channel P1 to be located in the signal channel P1. As shown in FIG. 11, in the non-pressed state (the keycap end 121a at the upper point HP1), the shield 16 is disposed over the signal channel P1 at an initial angle θ1 (about 100 degrees). Referring to FIG. 7 and FIG. 8, in this embodiment, when the keycap end 121a (122a) is at the upper point HP1, the free end of the shield 16 extends through the upper threshold US1 to the lower threshold DS1, so the shield 16 shields two ends of the signal channel P1 from the upper threshold US1 to the lower threshold DS1 at the same time. With the inclined edges 161 at two sides of the shield 16, when the keycap end 121a is at the upper point HP1, and the free end of the shield 16 extends to the lower threshold DS1, the signal channel P1 is not completely shielded by the shield 16 in the width direction, and the region of the signal channel P1 that is not shielded by the shield 16 is located at the two sides of the shield 16. Accordingly, light emitted from the sensing light source 112 can still partially pass through the signal channel P1 from beside the two sides of the shield 16 to be received by the light sensor 113. From another aspect, as shown in FIG. 8, when the keycap end 121a is at the upper point HP1, and the shield 16 extends from the upper threshold US1 to the lower threshold hold DS1, the shield 16 partially overlaps the opening 111a since the width D2 of the opening 111a is larger than the width D3 of the free end of the shield 16, so the signal channel P1 is partially shielded by the shield 16, allowing a portion of light emitted from the sensing light source 112 to pass through the unshielded portion of the signal channel P1 to be received by the light sensor 113.

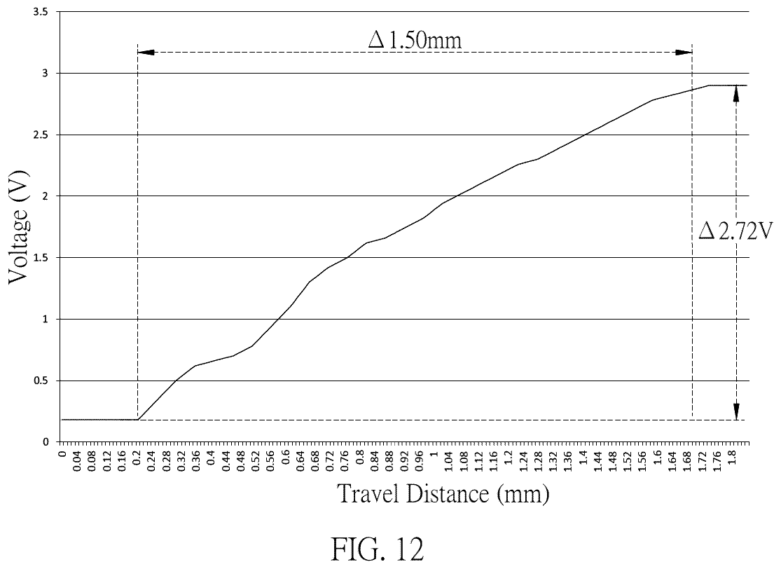

Moreover, the shield 16 can synchronously move upward or downward along with the keycap end 121a. Referring to FIG. 6, FIG. 8, and FIG. 12, when the keycap end 121a is at the upper point HP1, the free end of the shield 16 is stably located in the signal channel P1. At this state, the output voltage of the light sensor 113 is stably maintained at 0.2V, and the keyswitch circuit 115 outputs the null signal, indicating that the user does not press the keycap 13. When the user exerts a force on the keycap 13, the lifting mechanism 12 is driven by the force to drive the keycap end 121a (122a) to move downward from the upper point HP1. At this state, the shield 16 synchronously moves downward with the keycap end 121a, so the shield 16 flips in the signal channel P1 and increases an interference area of the shield 16 with the signal channel P1. Consequently, the amount of light that passes from two sides of the shield 16 to the light sensor 113 is gradually reduced, and the output voltage of the light sensor 113 is gradually increased from 0.2V to 2.92V as shown in FIG. 12. At this state, the signal channel P1 can still be not completely shielded by the shield 16, and with the inclined edges 161 at two sides of the shield 16, the distance (about 1.5 mm) of downward movement of the lifting mechanism 12 can be used as much as possible to cause the change of the output voltage of the light sensor 113. Moreover, referring to FIG. 9, during the movement of the keycap end 121a (122a) from the upper point HP1 to the lower point LP1, the free end of the shield 16 moves downward to pass through the through hole 114 and extends through the upper surface and the lower surface of the substrate 11 to prevent the interference of the shield 16 with the substrate 11. Referring to FIG. 9 and FIG. 10, when the keycap end 121a moves to the lower point LP1, the shield 16 exhibits a state of substantially perpendicular to the substrate 11, i.e., the shield 16 flips about 10 degrees during the travel distance, and the shield 16 completely shields the signal channel P1, i.e., the portion of the shield 16 in the signal channel P1 is larger than the opening 111a in dimension. With the design of the shield 16 substantially perpendicular to the substrate 11, the shield 16 can be prevented from flipping beyond the perpendicular line, causing the inference area to be reversely decreased to output a false signal caused by misjudgment.

More specifically, as shown in FIG. 12, when the user presses the keycap 13 to drive the lifting mechanism 12 to move the keycap end 121a downward from the upper point HP1, and the interference area of the shield 16 with the signal channel P1 (i.e., the area of the signal channel P1 shielded by the shield 16 along the B-B direction) is gradually increased to an extent that the output voltage of the light sensor 113 is gradually increased to exceed 0.3V, the keyswitch circuit 115 outputs the first keyswitch signal. Through the design that the signal is generated only when the voltage exceeds 0.3V, misjudgment that the keyswitch circuit 115 is activated by the fluctuation of the output voltage of the light sensor 113 caused by interference from the light or slightly shaking can be prevented. When the user keeps pressing the keycap 13, the area that the shield 16 interferes with the signal channel P1 is continuously increased. When the keycap end 121a moves downward to about 0.9 mm of the travel distance, the output voltage of the light sensor 113 is gradually increased to exceed 1.8V. At this stage, the keyswitch circuit 115 outputs the second keyswitch signal. The electronic device that receives the keyswitch signals (e.g. computer mother board, processor, etc.) can perform a subsequent operation in response to receiving the first keyswitch signal or the second keyswitch signal. For example, when the electronic device receives the first keyswitch signal, indicating that the user slightly presses the keyswitch assembly 1, the electronic device will perform a corresponding operation that “the character walks slowly”. When the electronic device receives the second keyswitch signal, indicating that the user heavily presses the keyswitch assembly 1, the electronic device will perform a corresponding operation that “the character runs”. As such, the aforementioned design of the keyswitch assembly 1 can be applied to keyswitches (such A key, S key, D key, W key, ↑key, ↓key, ←key, →key) of the electronic device that control the character, to achieve the effect of fine control without affecting the thinning requirement of the keyswitch assembly 1. In addition to the above threshold settings, the user can adjust or change to 3 or more signal differences according to different usage needs. For example, when the light sensor 113 senses the optical signal to output a voltage below 0.3V, the keyswitch circuit 115 outputs a null signal. When the light sensor 113 outputs a voltage reaching 0.3V, the keyswitch circuit 115 outputs the first keyswitch signal for the electronic device to perform the control of “sneaking slowly”. When the light sensor 113 outputs a voltage reaching 1.2V, the keyswitch circuit 115 outputs the second keyswitch signal for the electronic device to perform the control of “walking”. When the light sensor 113 outputs a voltage reaching 2.1V, the keyswitch circuit 115 outputs the third keyswitch signal for the electronic device to perform the control of “running”.

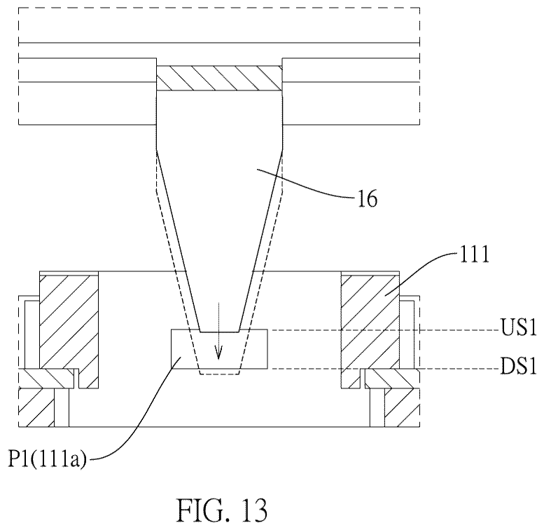

It is noted that in practical applications, the shield of the invention can be disposed on the keycap or formed by extending from the bottom of the keycap as long as the shield can move upward or downward synchronously with the lifting mechanism to achieve the effect of the aforementioned embodiment. When the keycap end 121a is at the upper point, the free end of the shield 16 extends from the upper threshold US1 to the lower threshold DS1 as described above. Alternatively, as shown in FIG. 13, the free end of the shield 16 can pass only the upper threshold US1 (not reaching the lower threshold DS1) to achieve the effect of the aforementioned embodiment. The free end of the shield 16 is designed to at least pass the upper threshold US1 for the purpose that when the lifting mechanism 12 operates, the light sensor 113 can immediately sense the change in interference of the signal channel P1, which can greatly reduce the moving distance that light sensor 113 is unable to sense the change in interference of the signal channel. As such, the effect that the moving distance of the lifting mechanism 12 can be used as much as possible to cause the change of the output voltage of the light sensor 113 can be achieved.

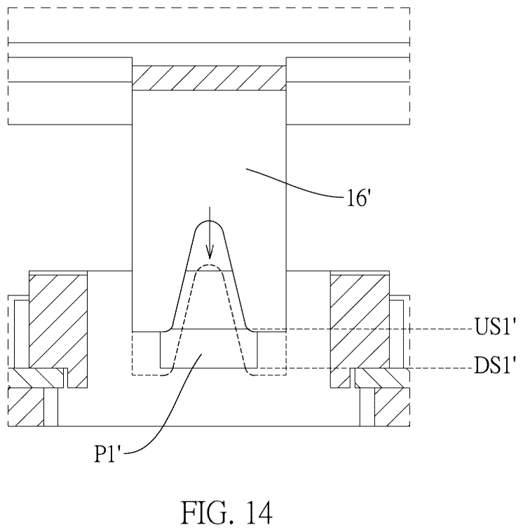

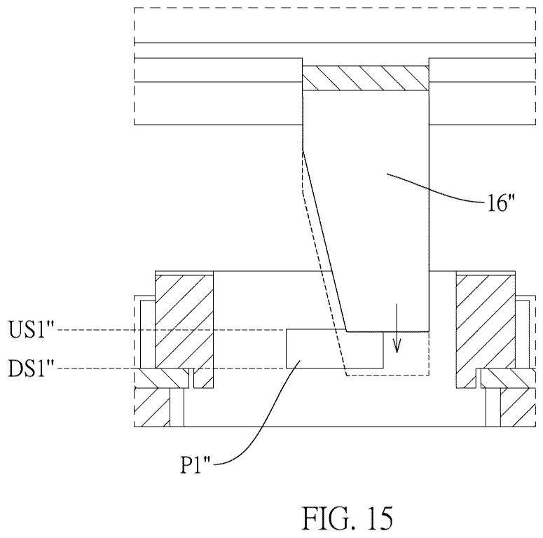

In addition to the structure of the shield 16 having the pair of inclined edges 161 at two outer sides, as shown in FIG. 14, the shield 16′ can be designed to have a pair of inclined edges at two inner sides, or as shown in FIG. 15, the shield 16″ can be designed to have a single inclined edge at one side. When the shield 16, 16′, or 16″ moves downward with the freed end reaching the lower threshold DS1, DS1′, or DS1″ and shielding the upper threshold US1, US1′, or US1″ and the lower threshold DS1, DS1′, or DS1″ at the same time, the signal channel P1, P1′, or P1″ is not completely shielded by the shield 16, 16′, or 16″, and the effect of the aforementioned embodiment can be achieved.

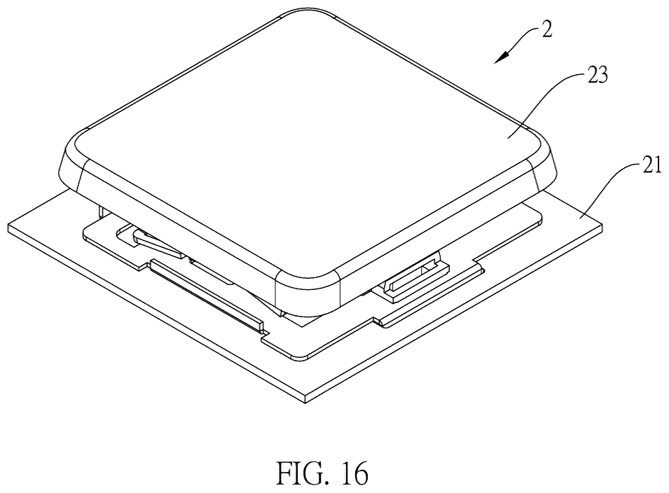

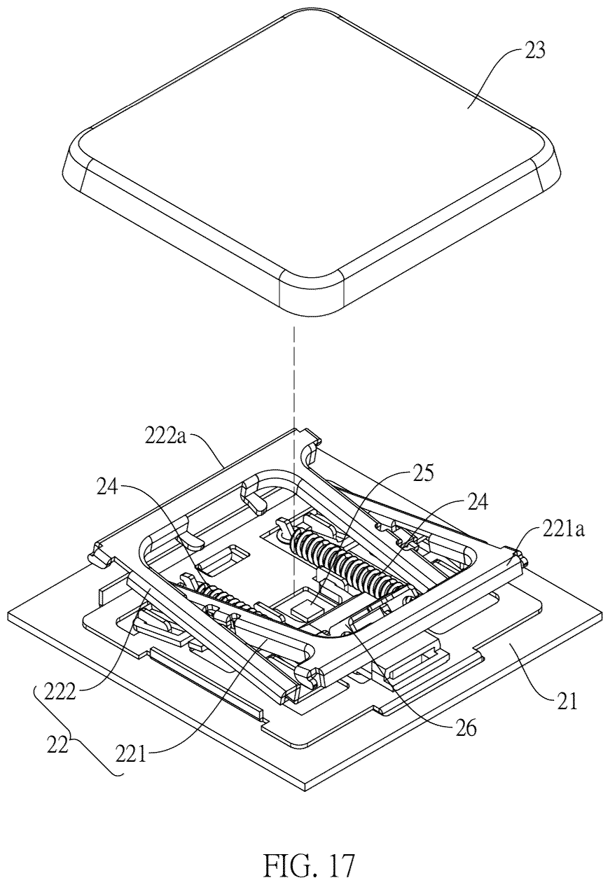

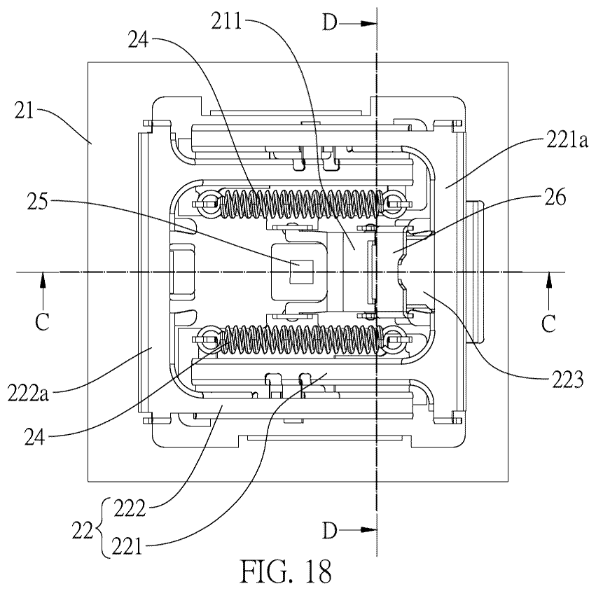

Referring to FIG. 16 to FIG. 18, the keyswitch assembly 2 of the third embodiment includes a substrate 21, a lifting mechanism 22, a keycap 23, a restoring member, a backlight source 25, and a linking member 26.

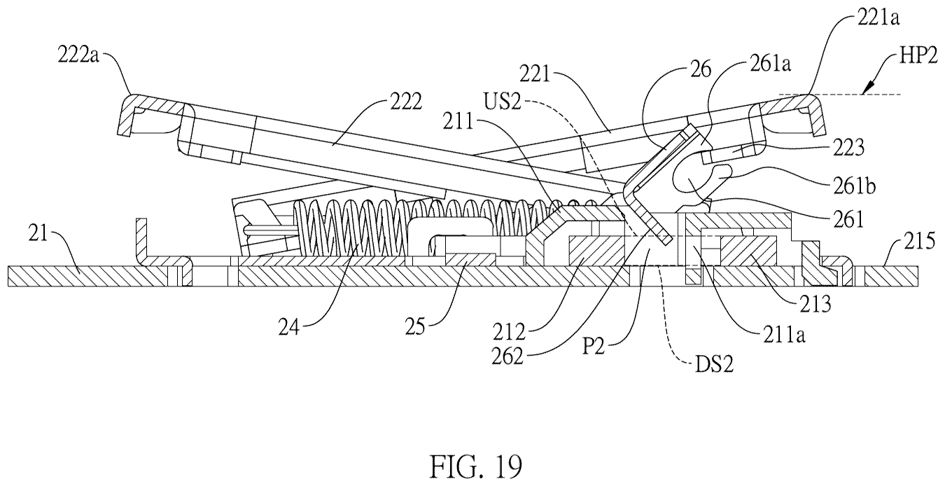

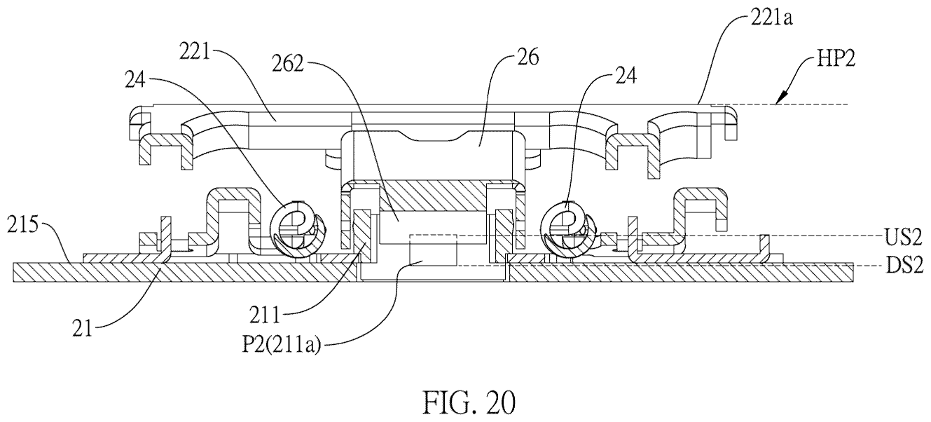

Referring to FIG. 19 and FIG. 20, similarly, the substrate 21 includes a sensing switch, an optical member 211, and a keyswitch circuit 215. More specifically, in this embodiment, the sensing switch includes a sensing light source 212 and a light sensor 213 disposed opposite to each other. The optical member 211 covers the light sensor 213 of the sensing switch, and the optical member 211 has an opening 211a. The light sensor 213 faces the sensing light source 212 through the opening 211a, so a signal channel P2 is defined between the light sensor 213 and the sensing light source 212 through the opening 211a. According to the height and the width of the signal channel P2, the signal channel P2 is configured with two thresholds at two opposite ends between the sensing light source and the light sensor, respectively). For example, the signal channel P2 can be defined with an upper threshold US2 and a lower threshold DS2 similar to the above embodiment. When the signal channel P2 is interfered, the sensed intensity of the light sensor 213 will be changed, and the output voltage is correspondingly changed. The keyswitch circuit 215 is disposed on the substrate 21 and electrically connected to the light sensor 213. When the sensed signal of the light sensor 213 of the sensing switch is changed, the keyswitch circuit 215 will generate the keyswitch signal. More specifically, in this embodiment, the keyswitch circuit 215 can be configured with a plurality of threshold values different from each other. When the sensed intensity of the light sensor 213 reaches a corresponding threshold value, the keyswitch circuit 215 will generate a keyswitch signal corresponding to the reached threshold value.

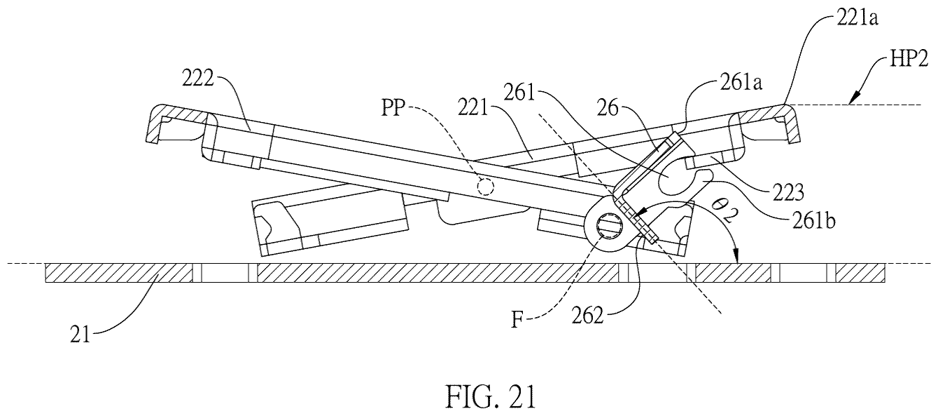

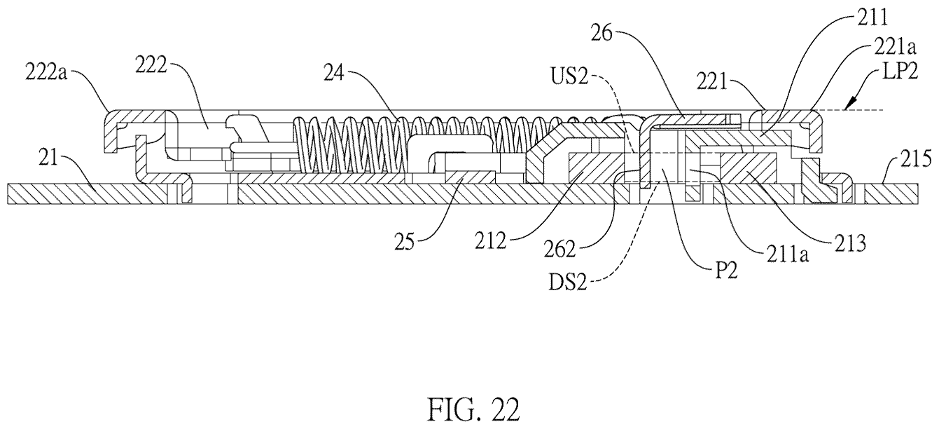

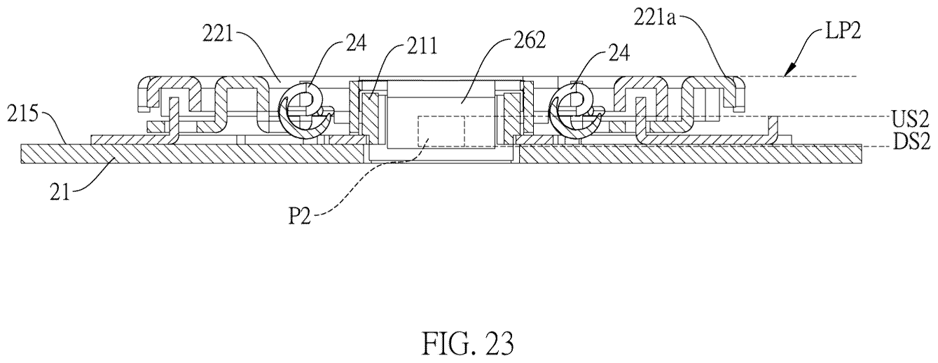

Referring to FIG. 21, the lifting mechanism 22 includes a first frame 221 and a second frame 222. The first frame 221 and the second frame 222 are connected to each other and rotatable with a pivot point PP as a rotation axis. The top portion of each of the first frame 221 and the second frame 222 constitutes a keycap end 221a (222a), which is configured to connect the keycap 23. The bottom portion of each of the first frame 221 and the second frame 222 constitutes a substrate end, which is configured to connect the substrate 21. The structure of how the lifting mechanism 22 movably connects the keycap 23 and the substrate 21 is a conventional technology and will not be elaborated. The lifting mechanism 22 is different from the above embodiment in that the first frame 221 has a buckle member 223, which is formed closer to the top portion and extends toward the pivot point PP. When the user presses the keycap 23, the lifting mechanism 22 is driven by the force to move by a distance to drive the keycap end 221a to move from the upper point HP2 (as shown in FIG. 19 and FIG. 20) to the lower point LP2 (as shown in FIG. 22 and FIG. 23), and the buckle member 223 is driven to move simultaneously.

The restoring member can include two tension springs 24, which are located between the first frame 221 and the second frame 222 and connected to the hooks at the substrate ends of the first frame 221 and the second frame 222, so the keycap end 221a can be driven to return from the lower point LP2 to the upper point HP2. The backlight source 25 can be an LED, which is disposed on the substrate 21 at the central region defined by the lifting mechanism 22 and configured to emit light, which is projected to the keycap 23, so the pattern (not shown) on the top of the keycap 23 can be penetrated by the light to display the pattern content.

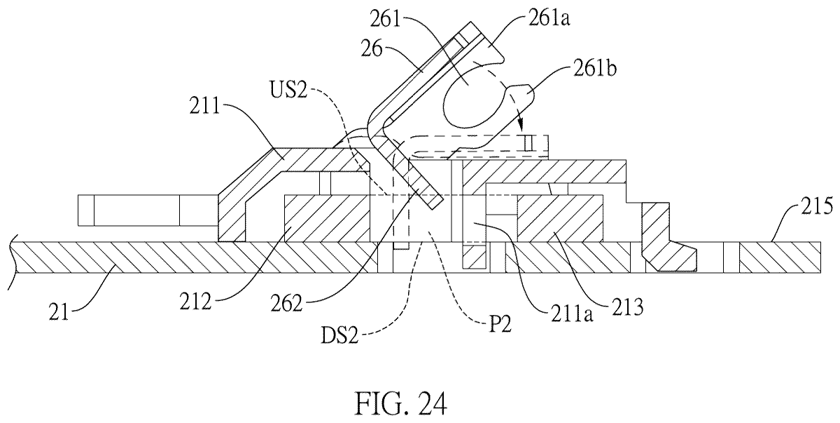

The linking member 26 is pivotally disposed on the optical member 211, so the linking member 26 is located between the keycap end 221a and the backlight source 25. Referring to FIG. 21 and FIG. 24, the pivotal portion of the linking member 26 is defined as a linkage fulcrum F, and the linking member 26 can rotate relative to the optical member 211 with the linkage fulcrum F as the rotation axis. Moreover, one end of the linking member 26 is formed with a notch 261, and the notch 261 is movably connected to the buckle member 223, so the linking member 26 is attached to the first frame 221. The notch 261 has an upper jaw 261a and a lower jaw 261b, and the buckle member 223 is located between the upper jaw 261a and the lower jaw 261b. The other end of the linking member 26 is bent downward to form a shield 262. When the linking member 26 is attached to the first frame 221, and the keycap end 221a is at the upper point HP2, as shown in FIG. 19 to FIG. 21, the shield 262 is disposed over the signal channel P2 at an initial angle θ2 (about 133 degrees), and the free end of the shield 262 passes the upper threshold US2 of the signal channel P2 to be located in the signal channel P2. With the design that the linking member 26 is pivotally disposed on the optical member 211, and the notch 261 is attached to the buckle member 223, the shield 262 can move upward or downward with the keycap end 221a. More specifically, when the keycap end 221a moves downward from the upper point HP2 to the lower point LP2, the buckle member 223 will push the lower jaw 261b to drive the linking member 26 to rotate downward, so the shield 262 is driven to move downward. On the other hand, when the keycap end 221a moves upward from the lower point LP2 to the upper point HP2, the buckle member 223 will push the upper jaw 261a to drive the linking member 26 to rotate upward, so the shield 262 is driven to move upward.

Referring to FIG. 19 to FIG. 21, when the keycap end 221a is at the upper point HP2, the free end of the shield 262 is stably located in the signal channel P2 (the keyswitch circuit 215 outputs a null signal at this stage). When the user starts to press the keycap 23, the lifting mechanism 22 is driven by the force to move the keycap end 221a downward from the upper point HP2. At this stage, the linking member 26 is driven to rotate downward relative to the optical member 211 with the linkage fulcrum F as the rotation axis, causing the shield 262 to descend. As shown in FIG. 24, the shield 262 rotates in the signal channel P2 while moving downward to gradually increase the interference area with the signal channel P2, so light emitted from the sensing light source 212 to be received by the light sensor 213 is gradually decreased, and the voltage output from the light sensor 213 is gradually increased (the keyswitch circuit 215 will correspondingly output different keyswitch signals such as the first keyswitch signal or the second keyswitch signal according to the output voltage). With the design that the linking member 26 is pivotally disposed on the optical member 211, and the buckle member 223 drives the linking member 26 to rotate, the larger moving distance (about 1.5˜1.7 mm) of the lifting mechanism 22 can be converted into the rotation of the shield 262 with the smaller moving distance (about 0.56 mm), so the entire moving distance of the lifting mechanism 22 can be used as much as possible to cause the change of the output voltage of the light sensor 213.

Moreover, during the movement of the keycap end 221 a from the upper point HP2 to the lower point LP2, the shield 262 rotates and slightly descends, so the free end of the shield 262 will not extend beyond the substrate 21. In other words, the shield 262 will not penetrate through the substrate 21, so the keyswitch assembly 2 can have a thinner configuration. Referring to FIG. 21 and FIG. 24, when the keycap end 221a is at the upper point HP2, the shield 262 is hung over the signal channel P2 at the initial angle θ2 (about 133 degrees). When the keycap end 221a moves to the lower point LP2, the shield 262 is substantially perpendicular to the substrate 21. In the entire travel distance of the lifting mechanism 22, the shield 262 flips about 43 degrees, which is larger than the flipping angle (about 10 degrees) of the first frame 221. With the design that the shield 262 is substantially perpendicular to the substrate 21, the shield 262 can be prevented from flipping beyond the perpendicular line, causing the inference area to be reversely decreased to output a false signal caused by misjudgment. However, in practical applications, the flipping angle of the shield 262 is not limited to the above angle, and the flipping angle of the shield 262 can be selectively larger than 5 degrees, 10 degrees, 20 degrees, 30 degrees, or 40 degrees according to design parameters, such as the dimension (e.g. height) of the signal channel P2, the area of the shield 262, and the distance between the shield 262 and the signal channel.

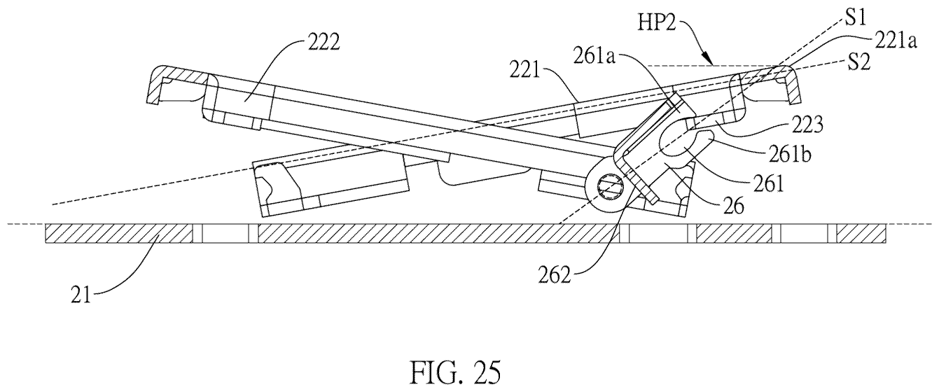

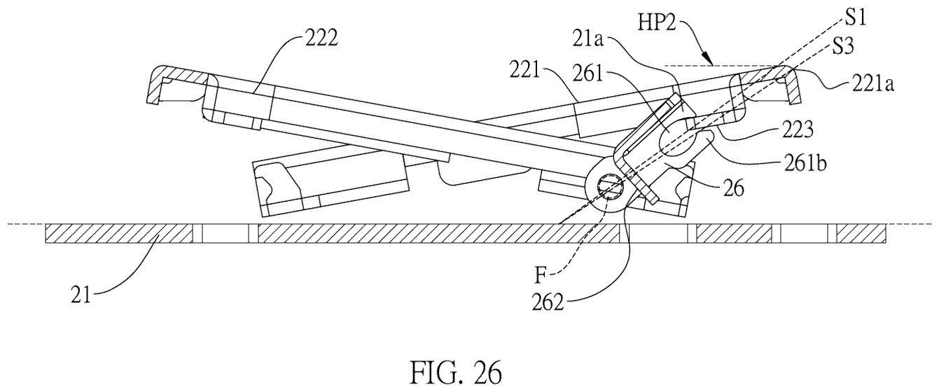

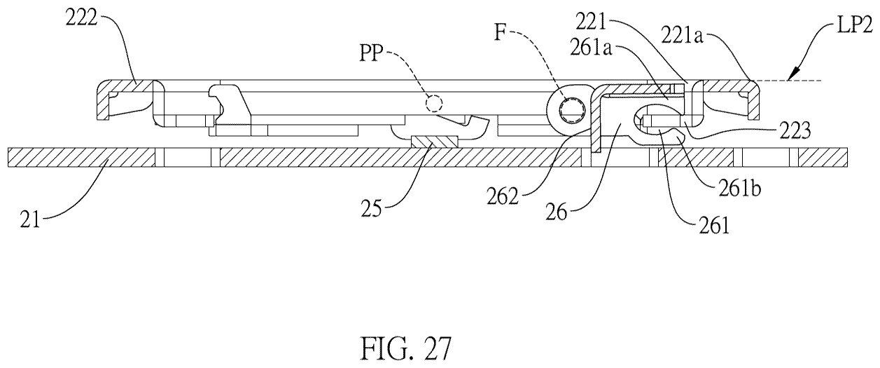

In order to prevent the linking member 26 from interfering with other components during the movement and to move the linking member 26 more smoothly, the linking member 26 and the first frame 221 to which is attached preferably satisfy the following conditions:
(1) As shown in FIG. 25, in the non-pressed state (i.e., the keycap end 221a is at the upper point HP2), with reference to the supper surface of the substrate 21, the linkage slope S1 of the linking member 26 is larger than the frame slope S2 of the first frame 221.
(2) As shown in FIG. 26, with reference to the upper surface of the substrate 21, the equivalent slope S3 of the keycap end 221a of the first frame 221 relative to the linkage fulcrum F approximates to the linkage slope S1 of the linking member.
(3) As shown in FIG. 27, in the pressed state (i.e., the keycap end 221a is at the lower point LP2), the linkage fulcrum F is located between the keycap end 221a and the pivot point PP. More specifically, in the pressed state, the linkage fulcrum F is located between the keycap end 221a and the pivot point PP and substantially linearly aligned with the keycap end 221a and the pivot point PP along a direction parallel to the extension direction of the signal channel P2. In other words, when in the pressed state, the triangle formed by the linkage fulcrum F, the keycap end 221a and the pivot point PP in the cross section along the extension direction of the signal channel P2 has an apex angle at the linkage fulcrum F, and the apex angle preferably approximates 180 degrees, such as 170-180 degrees.

It is noted that in practical applications, the linking member of the invention can be pivotally disposed on the optical member or pivotally disposed on the substrate or other fixtures to rotate during the upward or downward movement of the lifting mechanism to achieve the effect described in the previous embodiments. Moreover, the shield 262 can have a plate shape or a configuration of the first embodiment, i.e., the shield 16 with a pair of inclined edges 161 at two outer sides, or a configuration of FIG. 14, i.e., the shield 16′ with a pair of inclined edges 161 at two inner sides, or a configuration of FIG. 15, i.e., the shield 16″ with one inclined edge at one side, to achieve the effect of the previous embodiments.

In the third embodiment, the linking member 26 is connected to the first frame 221 to be driven by the first frame 221 to drive the shield 262 to interfere with the signal channel P2 in an open to close manner. However, in practical applications, the linking member can be connected to the second frame 222 at the other side, so the working direction of the linking member will be opposite to the third embodiment, and the shield interferes with the signal channel in a close to open manner to achieve the same control effect.

In order to enhance the multi-stage control, the keyswitch assembly (e.g. 1 or 2) of the above embodiments can optionally include a stopper. Taking the keyswitch assembly 1 as an example, as shown in FIG. 6, a stopper 17 is disposed on the substrate 11 corresponding to the peripheral region of the lifting mechanism 12 or the keycap 13. More specifically, in the stacking (vertical) direction, the stopper 17 at least partially overlaps the lifting mechanism 12 or the keycap 13, so during the downward movement of the lifting mechanism 12, the lifting mechanism 12 or the keycap 13 (e.g. the keycap end) can move to press or hit the stopper 17. The stopper 17 is preferably made of a flexible material, such as rubber or mylar, to provide a resistant force when being pressed by the lifting mechanism 12 or the keycap 13. In an embodiment, the dimension (e.g. thickness) of the stopper 17 is preferably designed corresponding to the actuation point of the second keyswitch signal generated stage. For example, the upper surface of the stopper 17 preferably levels with the actuation point of the second keyswitch signal (e.g. heavy-pressing signal) in the height direction, but not limited thereto. In another embodiment, the upper surface of the stopper 17 can be located with the range between the actuation points of the first and second keyswitch signals. As such, when the lifting mechanism 12 is driven by the pressing force to move downward to the actuation point of the second keyswitch signal, the lifting mechanism 12 or the keycap 13 encounters the stopper 17, and the stopper 17 provides the resistant force to prolong the stay at the first keyswitch signal stage (e.g. light-pressing stage). Only when the user continuously increases the pressing force to overcome the resistant force provided by the stopper 17, the lifting mechanism 12 moves to the actuation point of heavy-pressing stage. Consequently, with the stopper 17, the user will be much easier to control the operations between the light-pressing and the heavy-pressing. It is noted that keyswitch assembly of the above embodiments may be provided with a plurality of stoppers 17, and the stoppers 17 may be different in thickness or rigidity, so stoppers different in height or rigidity can correspond to the actuation points of different stages to facilitate the multi-stage control.

Moreover, the sensing switch of the second and third embodiments use the sensing light source and the light sensor, but not limited thereto. The sensing switch can use a sensing magnetic source (e.g. magnet or electric magnet) and a magnetic sensor (e.g. Hall sensor), and the shield can include a magnetic shielding material, a magnetic permeability material, or magnetic material. The shield may not be disposed between the linear gap between the magnet and the Hall sensor as long as the shield can at least partially interfere with the magnetic signal path, causing the magnetic flux sensed by the Hall sensor to change to achieve the effect of the second and third embodiments.

Although the preferred embodiments of the invention have been described herein, the above description is merely illustrative. The preferred embodiments disclosed will not limit the scope of the invention. Further modification of the invention herein disclosed will occur to those skilled in the respective arts and all such modifications are deemed to be within the scope of the invention as defined by the appended claims.

What is claimed is:

1. A keyswitch assembly, comprising:
a keycap;
a lifting mechanism comprising a keycap end coupled to the keycap and capable of being driven by a force to move downward by a distance;
a shield extending from the keycap end or the keycap and movable along with the keycap end or the keycap; and
a substrate disposed below the lifting mechanism, the substrate comprising a sensing switch and a keyswitch circuit electrically connected to each other, the sensing switch having a signal channel and configured to sense a change in sensed intensity caused by interference of the shield with the signal channel to cause the keyswitch circuit to generate at least one keyswitch signal,
wherein when the shield shields two opposite ends of the signal channel at the same time, the signal channel is not completely shielded by the shield.

2. The keyswitch assembly of claim 1, wherein the keyswitch circuit is configured with a plurality of threshold values different from each other; when the sensed intensity reaches a corresponding one of the plurality of threshold values, the keyswitch circuit generates one of the at least one keyswitch signal corresponding thereto.

3. The keyswitch assembly of claim 1, wherein the signal channel is defined with an upper threshold and a lower threshold at the two opposite ends, respectively; the lower threshold is closer to an upper surface of the substrate than the upper threshold; when a free end of the shield reaches the lower threshold, the signal channel is not completely shielded by the shield.

4. The keyswitch assembly of claim 1, wherein when the lifting mechanism moves downward by the distance, the keycap end moves from an upper point to a lower point; when the shield shields the two opposite ends of the signal channel at the same time, the keycap end does not reach the lower point.

5. The keyswitch assembly of claim 1, wherein the shield has a pair of inclined edges at two sides; when the shield shields the two opposite ends of the signal channel at the same time, a region of the signal channel not shielded by the shield is located at two sides of the shield.

6. The keyswitch assembly of claim 1, wherein a width of the shield at a portion connected to the keycap end is larger than a width of the signal channel; a width of the shield at a free end thereof is smaller than the width of the signal channel.

7. The keyswitch assembly of claim 1, wherein when the lifting mechanism moves downward by the distance, the keycap end is driven to move from an upper point to a lower point; when the keycap end reaches the lower point, a free end of the shield extends beyond an upper surface of the substrate.

8. The keyswitch assembly of claim 1, further comprising a backlight source disposed on the substrate and located at a central region defined by the lifting mechanism; the shield is located between the keycap end and the backlight source.

9. A keyswitch assembly, comprising:
a keycap;
a lifting mechanism comprising a keycap end coupled to the keycap and capable of being driven by a force to move downward by a distance;
a linking member movably against the lifting mechanism or the keycap and capable of moving along with the keycap end or the keycap, the linking member having a shield; and
a substrate disposed below the lifting mechanism, the substrate comprising a sensing switch and a keyswitch circuit electrically connected to each other, the sensing switch having a signal channel and configured to sense a change in sensed intensity caused by interference of the shield with the signal channel to cause the keyswitch circuit to generate at least one keyswitch signal,
wherein in a single travel distance of the lifting mechanism, a shield flipping angle of the shield is larger than a frame flipping angle of the keycap end.

10. The keyswitch assembly of claim 9, wherein in the single travel distance of the lifting mechanism, the shield flips in the signal channel and changes an interference area of the shield with the signal channel.

11. The keyswitch assembly of claim 9, wherein when the lifting mechanism moves downward by the distance, the keycap end is driven to move from an upper point to a lower point; when the keycap end is at the upper point, the shield is disposed over the signal channel at an initial angle; when the keycap end is at the lower point, the shield is perpendicular to the substrate.

12. The keyswitch assembly of claim 11, wherein in the single travel distance of the lifting mechanism, the shield flipping angle of the shield in the signal channel is larger than 5 degrees.

13. The keyswitch assembly of claim 9, wherein the linking member has an upper jaw and a lower jaw movably connected to the lifting mechanism or the keycap; when the keycap moves downward, the lifting mechanism or the keycap pushes the lower jaw to move the shield downward; when the keycap moves upward, the lifting mechanism or the keycap pushes the upper jaw to move the shield upward.

14. The keyswitch assembly of claim 9, wherein the substrate further comprises an optical member covering the sensing switch; the optical member has an opening to expose the signal channel.

15. The keyswitch assembly of claim 9, further comprising a backlight source disposed on the substrate and located at a central region defined by the lifting mechanism; the linking member is located between the keycap end and the backlight source.

16. The keyswitch assembly of claim 9, wherein when the shield shields two opposite ends of the signal channel at the same time, the signal channel is not completely shielded by the shield.

17. A keyswitch assembly, comprising:
a keycap;
a lifting mechanism comprising a keycap end coupled to the keycap, the keycap end capable of being driven by a force to move downward by a distance from an upper point to a lower point;
a linking member movably against the lifting mechanism or the keycap and capable of moving along with the keycap end or the keycap, the linking member having a shield; and
a substrate disposed below the lifting mechanism, the substrate comprising a sensing switch and a keyswitch circuit electrically connected to each other, the sensing switch having a signal channel and configured to sense a change in sensed intensity caused by interference of the shield with the signal channel to cause the keyswitch circuit to generate at least one keyswitch signal,
wherein the lifting mechanism has a pivot point, the linking member has a linkage fulcrum, and when the keycap end is at the lower point, the linkage fulcrum is located between the keycap end and the pivot point.

18. The keyswitch assembly of claim 17, wherein the lifting mechanism comprises a first frame; the linking member is attached to the keycap end of the first frame; in a non-pressed state, a linkage slope of the linking member is larger than a frame slope of the first frame.

19. The keyswitch assembly of claim 17, wherein the lifting mechanism comprises a first frame; the linking member is attached to the keycap end of the first frame; an equivalent slope of the keycap end relative to the linkage fulcrum approximates to a linkage slope of the linking member.

20. The keyswitch assembly of claim 17, wherein the substrate further comprises an optical member covering the sensing switch; the linkage fulcrum is located on the optical member or the substrate.
